(19) United States
(12) Patent Application Publication
(10) Pub. No.: US 2008/0224191 A1
(43) Pub. Date: Sep. 18, 2008

(54) Image pickup device with prevention of leakage current

(76) Inventors: Jung-Chak Ahn, Yongin-Si (JP); Yi-Tae Kim, Hwaseong-Si (KR); Kyung-Ho Lee, Suwon-Si (KR); Hyuck-In Kwon, Seoul (KR); Ju-Hyun Ko, Seongnam-Si (KR); Tetsuo Asaba, Suwon-Si (KR); Jong-Jin Lee, Seoul (KR); Su-Hun Lim, Suwon-Si (KR); Jung-Yeon Kim, Jin-Gu (KR); Se-Young Kim, Suwon-Si (KR); Sung-In Hwang, Seoul (KR)

Correspondence Address: LAW OFFICE OF MONICA H CHOI, P O BOX 3424, DUBLIN, OH, 430160204, US

(21) Appl. No.: 12/074,573

(22) Filed: Mar. 5, 2008

(30) Foreign Application Priority Data
Mar. 12, 2007 (KR) 2007-24091

(51) Int. Cl. H01L 31/101

(52) U.S. Cl. 257/292; 257/E31.054

(57) ABSTRACT

An image pickup device includes an active pixel sensor (APS), a row driver, and a leakage current breaker. The active pixel sensor includes an array of a plurality of pixels. The row driver selects at least one pixel to be activated to output signals. The leakage current breaker decreases the leakage current through the unselected pixels by applying a leakage current breaker voltage at the bit lines of the APS array.

This application claims priority under 35 USC §119 to Korean Patent Application No. 2007-24091 filed on Mar. 12, 2007 in the Korean Intellectual Property Office, the disclosure of which is incorporated herein in its entirety by reference.

### BACKGROUND OF THE INVENTION

1. Field of the Invention

The present invention relates generally to image pickup devices such as CIS (CMOS image sensor) devices, and more particularly, to an image pickup device with prevention of leakage current through depletion or epitaxial type transistors therein.

2. Background of the Invention

A complementary metal-oxide semiconductor (CMOS) image sensor as an example image pickup device is widely used in digital cameras for converting optical images into electrical signals. Such conversion occurs at pixels of the CMOS image sensor with each pixel having a respective photodiode and a respective pixel circuit. The photodiode generates electric charges from received light, and the pixel circuit converts the electric charges into electric analog signals. Such analog signals are transmitted to a read-out circuit that converts the analog signals into digital signals.

Generally, each pixel includes enhancement type MOSFETs (metal oxide semiconductor field effect transistors) for the pixel circuit. FIG. 1 is a cross-sectional view of an enhancement type NMOSFET (N-channel metal oxide semiconductor field effect transistor) used in the pixel circuit according to the prior art.

Referring to FIG. 1, the enhancement type NMOSFET includes a source region 3 and a drain region 4 that is of N+ type conductivity formed in a P-WELL 5 disposed in a P-epitaxial layer 7. The enhancement type NMOSFET also includes a gate 1 and a gate oxide 2. In the prior art enhancement type NMOSFET, an interface 6 between the gate oxide 2 and the P-WELL 5 may include an interface trap from a slight gap between the gate oxide 2 and the P-WELL 5. The interface trap includes electrons that move therein even when a pixel does not operate, and especially from external temperature change.

With such movement of electrons in the interface trap, a small channel with unnecessary current flowing therein is formed at the interface 6 between the gate oxide 2 and the PWELL 5. Such undesired current is called a dark current. Additionally, such undesired current flow through the interface trap may further increase the occurrence of the interface trap.

Accordingly, even when a pixel does not receive light, the dark current through the interface trap causes an abnormal signal (i.e., noise) to be generated from the pixel. For reducing such noise, a depletion type NMOSFET is used in the pixel circuit.

A depletion type NMOSFET includes an N-type doped channel region formed between the source and the drain and below the gate oxide. Thus, the depletion type NMOSFET has a negative threshold voltage (V_{TH}<0). The depth of the N-type channel region increases with a positive voltage applied at the gate. Current flows through the entire N-type doped channel region even with electrons from the interface trap at the interface between the gate oxide and the N-type doped channel region such that the current flowing through such an interface is relatively reduced. Consequently, the pixel having the depletion type transistor has reduced dark current and thus reduced noise.

FIG. 2 illustrates an example column of an active pixel sensor array of the image pickup device using depletion type NMOSFETs in the CMOS image sensor according to the prior art. The active pixel sensor array includes a plurality of pixels arranged in rows and columns. FIG. 2 shows a plurality of pixels 11, 12, and 13 formed along an example column.

Referring to FIG. 2, each of the pixels 11, 12, and 13 includes a respective pixel circuit of four NMOSFETs MN1, MN2, MN3, and MN4 and a respective photodiode PD as illustrated for the example pixel 11. The NMOSFETs MN1, MN2, MN3, and MN4 are depletion type NMOSFETs. In addition, the pixels 11, 12, and 13 are connected to a bit line for the column of FIG. 2 at nodes N1, N2, and N3, respectively. A respective output terminal V_{OUT} is connected to a pull-up resistance (not shown) to set each node N1, N2, and N3 to about 0 Volt via an NMOSFET MN5 that is a bypass transistor. The NMOFSET MN5 is turned on from a control signal SH2 that is activated when a select control signal SEL applied on the NMOSFET MN4 is activated.

The NMOSFET MN2 resets a floating diffusion (FD) node of the pixel 11 according to a reset control signal RG. The NMOSFET MN1 transmits a charge signal from the photodiode PD according to a transmission control signal TG. The NMOSFET MN4 is turned on for selecting a pixel according to a select control signal SEL. The NMOSFET MN3 is a source follower that is used as a buffer to transmit image information of the pixel 11.

Assume that a row including the pixel 11 is selected to output image information with the select control signal SEL being activated for such a row. In that case, the NMOSFET MN4 for that row receives the select control signal SEL that is activated and the select control signal SEL to the other pixels 12 and 13 is deactivated. Thus, the NMOSFET MN4 for the pixel 11 is turned on by the activated select control signal SEL.

In that case, the pixel 11 outputs a reset signal voltage VRES as initialized by the reset control signal RG through the NMOSFETs MN3 and MN4 and an image signal voltage VSIG as transmitted from the photodiode PD through NMOSFETS MN1, MN3, and MN4. The reset signal voltage VRES and the image signal voltage VSIG are generated from signals at the output terminal V_{OUT} for correlated double sampling.

The corresponding NMOSFETs MN4 of the unselected pixels 12 and 13 are desired to be turned off by the corresponding select control signal SEL that is deactivated. However, such NMOSFETs MN4 in the unselected pixels 12 and 13 may actually be turned on especially when such NMOSFETs MN4 in the unselected pixels 12 and 13 are depletion type NMOSFETs having a negative threshold voltage.

The nodes N1, N2, and N3 are set to about 0 Volt such that about 0 Volt is applied to sources of the NMOSFETs MN4 of the unselected pixels 12 and 13. The deactivated select control signal SEL is at a logic low level such that the gate-to-source voltage of such NMOSFETs MN4 in the unselected pixels 12 and 13 is some-what higher than the negative threshold voltage V_{TH} of such NMOSFETs MN4.

As a result, leakage current flows through the NMOSFETs MN4 of the unselected pixels 12 and 13. Even if the amount of the leakage current flowing through each of the NMOSFETs MN4 of the unselected pixels 12 and 13 is relatively small, such leakage current flows through many unselected pixels coupled to the bit line of the column. Thus, the cumulative leakage currents flowing through the unselected pixels may become significant.

In addition, even when all the pixels 11, 12, and 13 of one column are not selected, the select NMOSFETs MN4 of such unselected pixels 11, 12, and 13 may not be completely turned off such that leakage current continuously flows as long as supply power is applied.

Unfortunately, such leakage current may deteriorate operation of the active pixel sensor array that outputs distorted signals because of such leakage current.

### SUMMARY OF THE INVENTION

Accordingly, a leakage current breaker is implemented into an image pickup device for preventing flow of such leakage current through depletion or epitaxial type transistors in the image pickup device.

An image pickup device according to an aspect of the present invention includes an active pixel sensor, a row driver, and a leakage current breaker. The active pixel sensor includes an array of a plurality of pixels. The row driver selects at least one pixel to be activated to output signals. The leakage current breaker prevents a respective leakage current through each of at least one unselected pixel.

In an example embodiment of the present invention, the leakage current breaker includes a respective leakage current breaker circuit coupled to each bit line for a respective column of pixels of the active pixel sensor. The respective leakage current breaker circuit applies a respective leakage current breaker voltage at each bit line when a select control signal for a selected row is activated.

The level of the activated leakage current breaker voltage is greater than the level of a deactivated select control signal applied on the unselected pixel. A plurality of select transistors for the pixels is coupled to a bit line. Thus, a respective select transistor for the selected row is turned on, and the remaining select transistors for the unselected rows are turned off from application of the respective leakage current breaker voltage at the bit line.

In another embodiment of the present invention, all respective select transistors for a selected row of the active pixel sensor are turned on, and all respective select transistors for unselected rows of the active pixel sensor are turned off, from application of the respective leakage current breaker voltage at all the bit lines of the active pixel sensor.

In an example embodiment of the present invention, the select transistors are depletion or epitaxial type MOSFETs (metal oxide semiconductor field effect transistors).

In another embodiment of the present invention, each epitaxial type MOSFET includes a source, a drain, an epitaxial-region, a gate oxide, and a gate electrode. The epitaxial-region is disposed between the source and the drain, with a channel region being disposed in the epitaxial-region between the source and the drain. The gate oxide is disposed on the epitaxial-region, and the gate electrode is disposed over the gate oxide.

In a further embodiment of the present invention, each epitaxial type MOSFET further includes a doped channel region formed by doping, with a first dopant of a first conductivity type, the epitaxial-region that is of a second conductivity type opposite to the first conductivity type.

In another embodiment of the present invention, each depletion or epitaxial type MOSFET includes a source and a drain formed along a first direction and a channel region formed between the source and the drain. Each depletion or epitaxial type MOSFET also includes isolation structures formed to abut the channel region along a second direction. Each depletion or epitaxial type MOSFET further includes a gate oxide disposed on the channel region and a gate electrode disposed over the gate oxide.

In an example embodiment of the present invention, each depletion or epitaxial type MOSFET also includes a respective well that is formed to surround each isolation structure including into the channel region under the gate oxide.

In an alternative embodiment of the present invention, each depletion or epitaxial type MOSFET includes a respective well that is formed to be under each isolation structure with full alignment or with partial alignment.

Such a MOSFET has the gate oxide that is disposed on the channel region formed by an epitaxial region for forming the epitaxial type MOSFET. Alternatively, the gate oxide is disposed on a doped channel region formed in the well or the epitaxial region for forming the depletion type MOSFET.

In a further embodiment of the present invention, each depletion type MOSFET further includes a doped channel region formed by doping, with a first dopant of a first conductivity type, the channel region that is of a second conductivity type opposite to the first conductivity type.

In an example embodiment of the present invention, the doped channel region does not abut the isolation structures. Alternatively, the doped channel region abuts the isolation structures.

In this manner, the leakage current breaker voltage is applied at the bit lines for preventing the leakage current through the select transistors of the unselected rows. With minimized leakage current, the select transistors of the selected row may output signals with high integrity.

### BRIEF DESCRIPTION OF THE DRAWINGS

The above and other features and advantages of the present invention will become more apparent when described in detailed exemplary embodiments thereof with reference to the attached drawings in which:

FIG. 1 is a cross-sectional view of an enhancement type field effect transistor used in a pixel of an image pickup device of the prior art;

FIG. 2 illustrates an example column of pixels in an image pickup device using depletion type field effect transistors according to the prior art;

FIG. 3 is a block diagram of an image pickup device with a leakage current breaker according to an embodiment of the present invention;

FIG. 4 illustrates an example column of pixels in the image pickup device of FIG. 3, according to an embodiment of the present invention;

FIG. 5 is a timing diagram of signals during operation of the pixels of FIG. 4, according to an embodiment of the present invention; FIG. 6 is a top view of a depletion or epitaxial type transistor used in the pixels of FIG. 4, according to an embodiment of the present invention;

FIGS. 7, 8, and 9 are sectional views of depletion or epitaxial type transistors used in the pixels of FIG. 4, taken along a line A of FIG. 6 according to embodiments of the present invention; and

FIGS. 10, 11, 12, 13, 14, 15, 16, 17, 18, 19, and 20 are sectional views of transistors used in the pixels of FIG. 4, taken along a line B of FIG. 6 according to embodiments of the present invention.

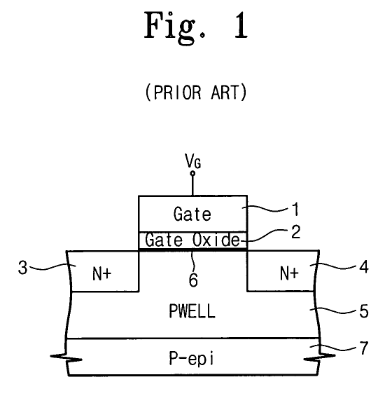

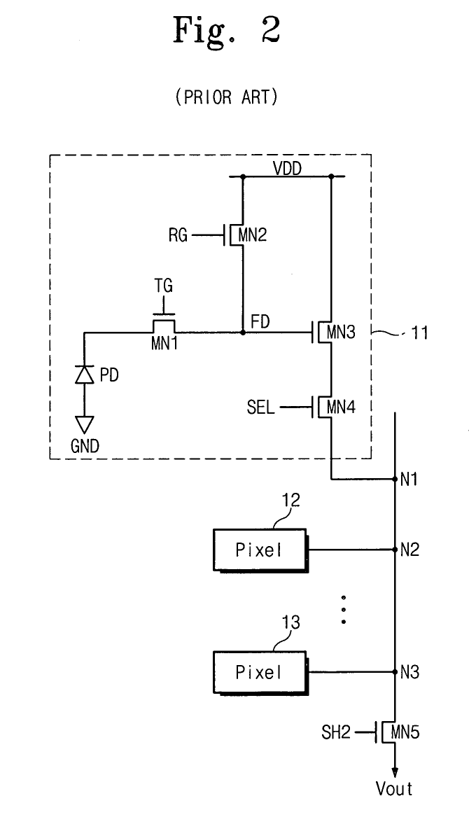

The figures referred to herein are drawn for clarity of illustration and are not necessarily drawn to scale. Elements having the same reference number in the above-identified figures refer to elements having similar structure and/or function.

### DETAILED DESCRIPTION OF THE INVENTION

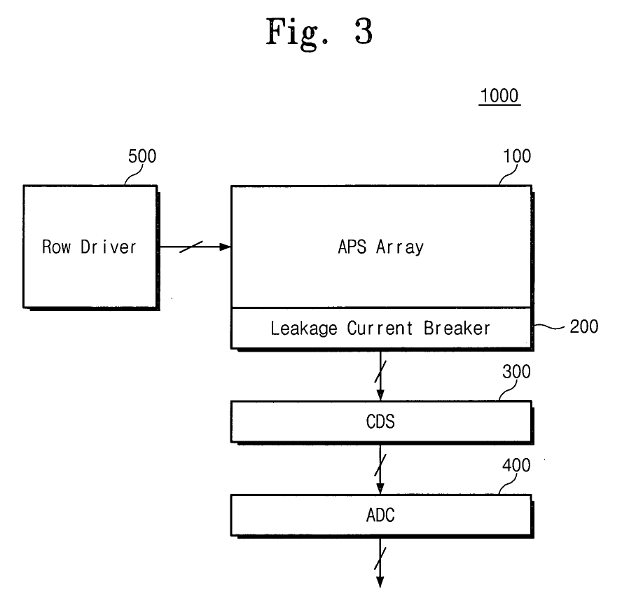

FIG. 3 shows a block diagram of an image pickup device 1000 according to an embodiment of the present invention. Referring to FIG. 3, the image pickup device 1000 includes an active pixel sensor (APS) array 100, a leakage current breaker 200, a correlated double sampling unit 300, an analog to digital converter (ADC) 400, and a row driver 500.

The APS array 100 includes a plurality of pixels arranged in rows and columns. Each pixel of the APS array 100 maintains an initialization state when unselected. The APS array 100 is controlled by the row driver 500. When a row of the APS array 100 is selected by the row driver 500, each pixel of the selected row is activated to generate a reset signal voltage VRES of an initialization state and an image signal voltage VSIG generated from received light.

The leakage current breaker 200 includes a respective leakage current breaker circuit for each column of pixels of the APS array 100. Each leakage current breaker circuit prevents leakage current of pixels in unselected rows in the corresponding column according to control from the row driver 500.

Additionally with control of the row driver 500, a respective reset signal voltage VRES and a respective image signal voltage VSIG are generated from each pixel of the selected row to the correlated double sampling unit 300. The correlated double sampling unit 300 and the ADC 400 include double sampling circuits corresponding to columns of the APS array 100. Accordingly, the correlated double sampling unit 300 and the ADC 400 have a column structure.

The correlated double sampling unit 300 performs correlated double sampling with the reset signal voltage VRES and the image signal voltage VSIG generated from each pixel of the selected row, and provides the result to the ADC 400. The ADC 400 converts the sampled analog signals into digital signals.

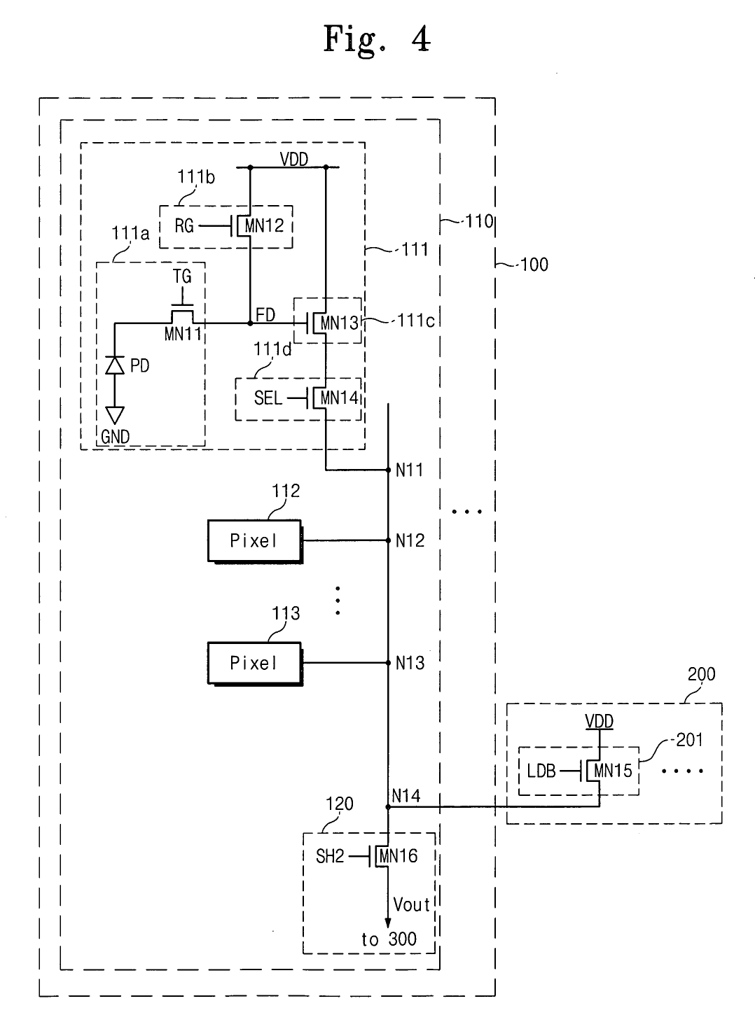

FIG. 4 illustrates one example column 100 of an active pixel sensor array of FIG. 3 with a respective leakage current breaker circuit 201 of the leakage current breaker 200. Referring to FIG. 4, the column 100 includes a respective plurality of pixels 111, 112, and 113 and the respective leakage current breaker circuit 201. The APS array 100 includes a plurality of columns that are each implemented with similar elements as the example column of FIG. 4.

Referring to FIG. 4, the example column 110 includes the plurality of pixels 111, 112, and 113, and a bypass circuit 120. Each of the pixels 111, 112, and 113 includes a respective detection circuit 111a, a respective reset circuit 111b, a respective source follower circuit 111c, and a respective select circuit 111d.

The detection circuit 111a includes a photodiode PD and a transmit NMOSFET (N-channel metal oxide semiconductor field effect transistor) MN11. The reset circuit 111b includes a reset NMOSFET MN12, and the source follower circuit 111c includes a source follower NMOSFET MN13. The select circuit 111d includes a select NMOSFET MN14. The bypass circuit 120 includes a bypass NMOSFET MN16.

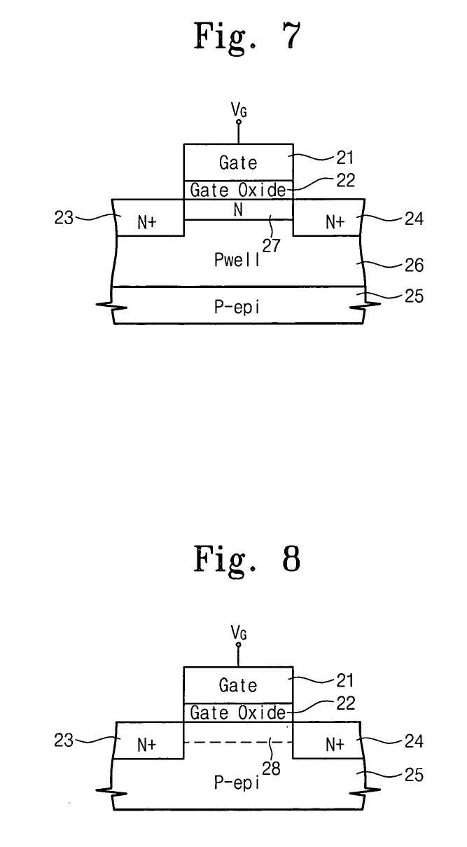

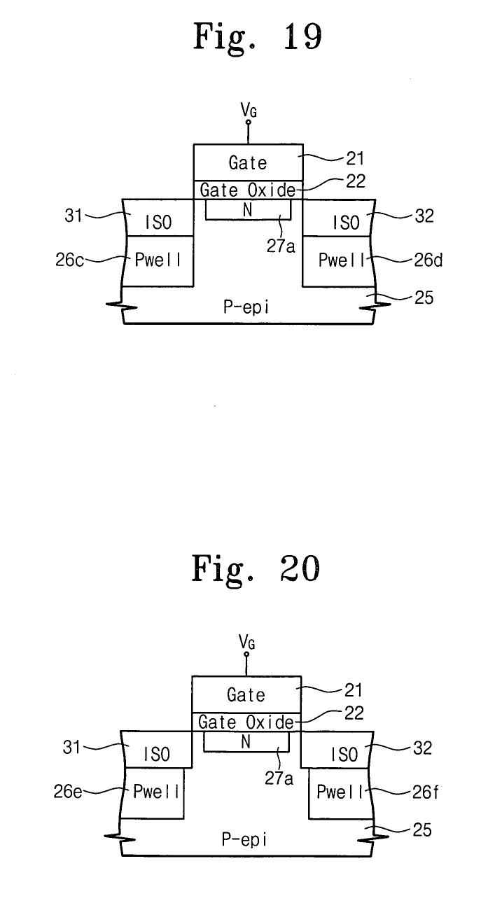

Each of the NMOSFETs MN2, MN3, and MN4 are depletion or epitaxial type NMOSFETs in an example embodiment of the present invention. Each of the pixels 111, 112, and 113 is implemented similarly as the example pixel 111. However, the present invention may also be practiced with the pixels including other transistors. Example implementations for the depletion or epitaxial type MOSFETs of the pixel 111 are described below in reference to FIGS. 7, 8, 9, 10, 11, 12, 13, 14, 15, 16, 17, 18, 19, and 20.

The photodiode PD of the detection circuit 111a is connected between a ground voltage GND and the transmit NMOSFET NM11 that is controlled by a transmission control signal TG. The transmit NMOSFET NM11 is connected between the photodiode PD and a floating diffusion (FD) node.

The reset NMOSFET MN12 initializes the pixel 111 in response to the reset control signal RG. The photodiode PD detects received light, and the transmit NMOSFET MN11 transfers a charge signal generated by the photodiode PD to the FD node. The select NMOSFET MN14 activates a pixel selected to output image information. The source follower NMOSFET MN13 is used as a buffer for transmitting image information for the pixel 111.

The bypass NMOSFET MN16 is turned on in response to the activated control signal SH2 to provide signals generated by the pixel 111 to the correlated double sampling unit 300. The leakage current breaker circuit 201 includes a leakage current breaker NMOSFET NM15 that is turned on to prevent leakage current in the unselected pixels.

The gate of the leakage current breaker NMOSFET NM15 has a leakage current breaker control signal LDB applied thereon. In addition, the leakage current breaker NMOSFET NM15 has a source connected to a node N14 and has a drain with a high supply voltage VDD applied thereon. The leakage current breaker unit 200 includes a plurality of leakage current breaker circuits 201 with a respective leakage current breaker circuit 201 being formed for each column of pixels.

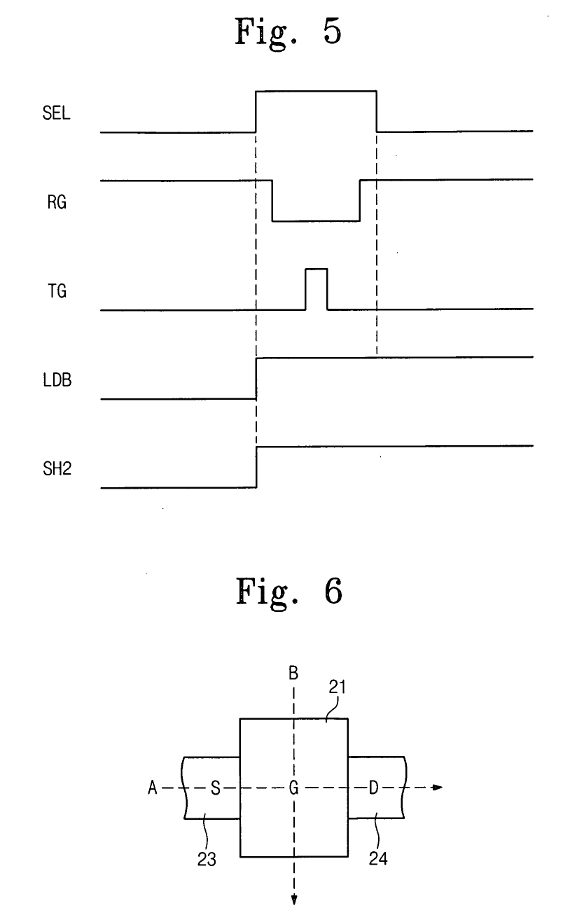

Control signals TG, RG, SEL, LDB, and SH2 applied on the elements of FIG. 4 and illustrated in FIG. 5 are generated by the row driver 500 in an example embodiment of the present invention. FIG. 5 is a timing diagram of such control signals TG, RG, SEL, LDB, and SH2 during operation of the elements of FIG. 4, according to an example embodiment of the present invention.

Operation of the example column of FIG. 4 is now described in reference to FIG. 5. The row driver 500 selects one row of the APS array 100 to output image information while the unselected rows do not operate to output image information. The row driver 500 activates the select control signal SEL to be provided to the selected row of pixels.

Also referring to FIGS. 4 and 5, upon activation of the select control signal SEL, the bypass control signal SH2 and the leakage current breaker control signal LDB are activated. The activated bypass control signal SH2 is applied at the gates of all respective bypass NMOSFETs MN16 for all columns in the APS array 100. In addition, the activated leakage current breaker control signal LDB is applied at the gates of all respective leakage current breaker NMOSFETs MN15 for all columns in the APS array 100. The row driver 500 maintains the leakage current breaker control signal LDB and the bypass control signal SH2 to be activated to the logical high state until all rows of the APS array 100 become selected to output image information, according to an embodiment of the present invention.

With activation of the leakage current breaker control signal LDB, the leakage current breaker NMOSFET MN15 is turned on. Accordingly, the high supply voltage VDD is applied on the node N14 through the leakage current breaker NMOSFET MN15. In addition, the other nodes N11, N12, and N13 for the bit line of the column of FIG. 4 are charged to the level of the high supply voltage VDD that is set to about 2 Volts for example. However, the present invention may be practiced with any level of the high supply voltage VDD. The voltage applied at the bit lines by the leakage current breaker circuits 201 is referred to as a leakage current breaker voltage.

The respective select NMMOSFET MN14 in each of the pixels 111, 112, and 113 is a depletion type NMOSFET and has a negative threshold voltage (V_{TH}<0), in an example embodiment of the present invention. Referring to FIGS. 4 and 5, assume that the pixel 111 is in the selected row while the remaining pixels 112 and 113 are in the unselected rows. Accordingly, the pixel 111 receives the respective select control signal SEL that is activated while the remaining pixels 112 and 113 each receive the respective select control signal SEL that is deactivated.

Further referring to FIGS. 4 and 5, the rows of pixels initially receive an activated reset control signal RG before being selected. This reset control signal RG is activated until the row driver 500 activates the select control signal SEL for indicating a selected row. Shortly thereafter, the reset control signal RG to the selected row is deactivated. That is, the unselected rows receive the activated reset control signal RG, and the selected row receives the reset control signal RG that is deactivated for a time period after the select control signal SEL is activated, as illustrated in FIG. 5.

Initially when each of the pixels 111, 112, and 13 receive the activated reset control signal RG, the gates of the reset NMOSFETs MN12 have the activated reset control signal RG applied thereon. Accordingly, the reset NMOSFETs MN12 in the pixels 111, 112, and 113 are turned on such that the high supply voltage VDD is provided to the floating diffusion nodes FD.

The source follower NMOSFET MN13 has a current flowing therein according to the level of the voltage applied to its gate. When the pixel 111 of the column 110 is selected by the row driver 500, the activated select control signal SEL is applied to the pixel 111. The activated select control signal SEL is at the logic high state and is typically a relatively high voltage such as about 5 Volts or 3.3 Volts for example.

The activated select control signal SEL is applied at the gate of the select NMOSFET MN14 while the leakage current breaker voltage of about 2 Volts is applied at the source of the select NMOSFET MN14 when the leakage current breaker NMOSFET NM15 is turned on. The level of the activated select control signal SEL is higher than the leakage current breaker voltage.

Accordingly, the gate-to-source voltage of the select NMOSFET MN14 is higher than the negative threshold voltage of the depletion type select NMOSFET MN14. Thus, the select NMOSFET MN14 is turned on such that a current flows through the source follower NMOSFET MN13 with the current level indicating the voltage at the gate of the source follower NMOSFET MN13. Such current flowing through the source follower NMOSFET MN13 flows to the output terminal Vout through the NMOSFETs MN13, MN14, and MN16. Such current level indicates the voltage at the gate of the source follower NMOSFET MN13, which is the floating diffusion node FD.

Initially such current indicates the reset signal voltage VRES applied at the gate of the source follower NMOSFET MN13. Subsequently, the select control signal SEL is activated, the reset control signal RG is deactivated, and the transmission control signal TG is activated as illustrated in FIG. 5. Accordingly, the reset NMOSFET MN12 is turned off and the transmission NMSOFET MN11 is turned on such that the image signal voltage VSIG corresponding to the light received at the photodiode PD is generated at the floating diffusion node FD.

The select NMOSFET MN14 is turned on such that a current flows through the source follower NMOSFET MN13 with a current level indicating the image signal voltage VSIG at the gate of the source follower NMOSFET MN13. Such current flowing through the source follower NMOSFET MN13 flows to the output terminal Vout through the NMOSFETs MN13, MN14, and MN16. Such current level indicates the image signal voltage VSIG at the gate of the source follower NMOSFET MN13, which is the floating diffusion node FD. The correlated double sampling unit 300 determines and performs double sampling with the reset signal voltage VRES and the image signal voltage VSIG to generate image information indicating the amount of light received at the photodiode PD.

The pixels 112 and 113 of the unselected rows receive the deactivated select control signal SEL which is about 0 Volt and is significantly lower than the leakage current breaker voltage. Thus, the gates of the select NMOSFETs MN14 of the unselected pixels 112 and 113 have the deactivated select control signal SEL applied thereon. Additionally as described above, the leakage current breaker voltage of about 2 Volts is applied to the sources of the select NMOSFETs MN14 of the unselected pixels 112 and 113.

In that case, the gate-to-source voltage of the select NMOSFETs MN14 of the unselected pixels 112 and 113 is lower than the negative threshold voltage of the depletion type select NMOSFETs MN14. Thus, the select NMOSFETs MN14 of the unselected pixels 112 and 113 are turned off such that leakage current does not flow through each of the select NMOSFETs MN14 of the unselected pixels 112 and 113. In addition, the select NMOSFETs MN14 of the unselected pixels 112 and 113 are turned off such that the unselected pixels 112 and 113 do not output image information.

The row driver 500 sequentially selects each of all the rows of the active pixel sensor array 100 such that all pixels of the rows perform respective light sensing operation. Referring to FIG. 5, the leakage current breaker control signal LDB and the bypass control signal SH2 remain activated until all the pixels of the rows are activated to output image information. Alternatively, according to user preference, the present invention may also be practiced when the leakage current breaker control signal LDB and the bypass control signal SH2 are activated when the select control signal SEL is activated, and are deactivated when the select control signal SEL is deactivated.

In any case, the leakage current breaker unit 200 prevents leakage current through the pixels of the unselected rows of the APS array 100. Accordingly, the image pickup device 1000 generates signals of image information with high integrity.

Each of the reset circuit 111b, the source follower circuit 111c, and the selection circuit 111d in the pixels of the APS array 100 may each include at least one depletion or epitaxial type MOSFET. Since a depletion type MOSFET has a negative threshold voltage, the dark current in the APS array 100 is minimized. If not the negative threshold voltage, a MOSFET of the epitaxial type with a very low threshold voltage may also prevent the dark current through the channel region. The epitaxial type MOSFET has a very low threshold voltage such as close to about 0 Volt.

FIG. 6 is a top view of a depletion or epitaxial type MOSFET used in the pixels of FIG. 4. FIGS. 7, 8, and 9 show cross-sectional views of a depletion type NMOSFET used in the pixels of FIG. 4 along line A of FIG. 6 according to embodiments of the present invention.

The transistor of FIG. 7 is a depletion type NMOSFET used in the pixels of FIG. 4, according to an example embodiment of the present invention. Referring to FIG. 7, the depletion type NMOSFET includes a source region 23 and a drain region 24 of N+ type conductivity in a P-WELL 26. The depletion type NMOSFET also includes a gate 21 on a gate oxide 22 and a P-epitaxial layer 25 below the P-WELL 26.

The P-well 26 is formed by doping a region in the P-epitaxial layer 25 such that the P-well 26 has a P-type dopant with higher concentration than a P-type dopant of the P-epitaxial layer 25. The depletion type transistor further includes a N-type doped channel region 27 formed by doping an N-type dopant into the P-well 26 between the drain and source regions 23 and 24. The gate oxide 22 is formed on the N-type doped channel region 27.

With the N-type doped channel region 27, the depletion type MOSFET has a negative threshold voltage (V_{TH}<0). With application of a positive gate-to-source voltage, the depth of the N-type channel region increases. With current flowing through the entire N-type channel region, current flow through the interface between the gate oxide 22 and the N-type channel region 27 is minimized. Consequently, a pixel with the depletion type NMOSFET of FIG. 7 has reduced dark current and improved noise characteristics.

The present invention may also be practiced with the NMOSFETs MN2, MN3, and MN4 being epitaxial type NMOSFETs in another embodiment of the present invention. A cross-sectional view of an epitaxial type NMOSFET is illustrated in FIG. 8. Referring to FIG. 8, a P-type epitaxial layer 25 is used to form the channel region between the source and drain regions 23 and 24.

The P-type epitaxial layer 25 is doped with a P-type dopant of relatively low concentration such that the threshold voltage of the epitaxial type NMOFET of FIG. 8 is close to 0 Volt. For example, if a P-well were formed in the P-type epitaxial layer 25 by doping with a higher P-type dopant concentration than the P-type epitaxial layer 25, the NMOSFET would be an enhancement type NMOSFET with a threshold voltage of 0.7 Volts or higher.

Instead, a region of the P-type epitaxial layer 25 between the source and drain regions 23 and 24 forms the channel region of the epitaxial type NMOSFET of FIG. 8 such that the threshold voltage is about 0 to 0.2 Volts. Growth of an epitaxial layer on a semiconductor substrate individually and in general is known to one of ordinary skill in the art.

Additionally, the epitaxial type NMOSFET of FIG. 8 does not include an N-type doped channel region such as the N-type doped channel region 27 in the NMOSFET of FIG. 7. The channel region 28 of the epitaxial type NMOSFET of FIG. 8 is formed when a gate voltage V_{G} is applied such that the gate-to-source voltage is higher than the threshold voltage of the epitaxial type NMOSFET. In addition, the depth of the channel region 28 increases with further depletion as the gate-to-source voltage is increased. Thus, the epitaxial type NMOSFET has reduced dark current and improved noise characteristics.

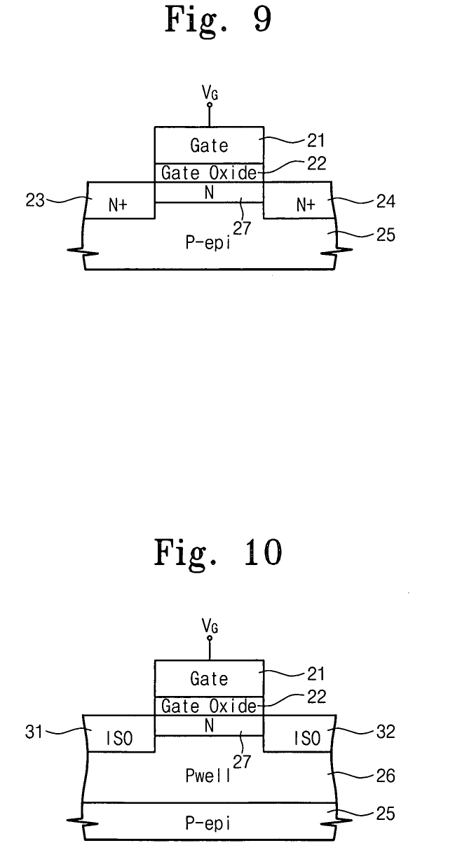

FIG. 9 shows a depletion type NMOSFET that may be used for the NMOSFETs MN2, MN3, or MN4 of FIG. 4 according to another embodiment of the present invention. Referring to FIGS. 8 and 9, the depletion type NMOSFET of FIG. 9 is formed by forming the N-type doped channel region 27 with doping of an N-type dopant in the P-type epitaxial layer 25. Thus, the depletion type NMOSFET of FIG. 9 has a negative threshold voltage.

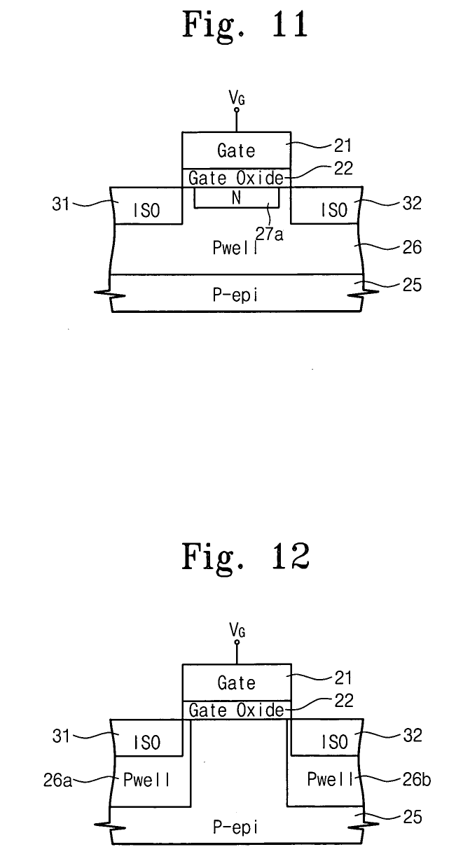

FIGS. 10, 11, 12, 13, 14, 15, 16, 17, 18, 19, and 20 are sectional views of the depletion type or epitaxial type NMOSFETs used in the pixels of FIG. 4, taken along a line B of FIG. 6 according to example embodiments of the present invention. FIGS. 10 and 11 are cross-sectional views of the depletion type NMOSFET of FIG. 7 according to an embodiment of the present invention.

Referring to FIG. 10, the depletion type NMOSFET includes isolation structures 31 and 32 formed in the P-WELL 26 to abut the N-type doped channel region 27 and to define the active region of the NMOSFET. Referring to FIGS. 6, 7, and 10, the source and drain regions 23 and 24 are formed to abut the channel region 27 along the first direction A in FIG. 6, and the isolation structures 31 and 32 are formed to abut the channel region 27 disposed under the gate 21 along the second direction B in FIG. 6. In the embodiment of FIG. 10, the N-type doped channel region 27 abuts the isolation structures 31 and 32.

The depletion type NMOSFET of FIG. 11 is similar to the depletion type NMOFET of FIG. 10 except that the depletion type NMOSFET of FIG. 11 has the N-type doped channel region 27 that does not abut the isolation structures 31 and 32. Thus, portions of the P-WELL 26 are disposed between the N-type doped channel region 27 and the isolation structures 31 and 32.

FIGS. 12, 13, and 14 are cross-sectional views of the epitaxial type NMOSFET of FIG. 8 along the line B of FIG. 6. Referring to FIG. 12, the epitaxial type NMOSFET includes isolation structures 31 and 32 formed in the P-type epitaxial layer 25 to abut the channel region formed by the P-type epitaxial layer 25.

Referring to FIGS. 6, 8, and 12, the source and drain regions 23 and 24 are formed to abut the channel region along the first direction A in FIG. 6, and the isolation structures 31 and 32 are formed to abut the channel region 27 disposed under the gate 21 along the second direction B in FIG. 6. Also in FIG. 12, a respective P-well 26a is formed to surround the isolation structure 31 including extending into the channel region under the gate 21, and a respective P-well 26b is formed to surround the isolation structure 32 including extending into the channel region under the gate 21.

The P-WELLs 26a and 26b extending into the channel region under the gate 21 cause the epitaxial NMOSFET of FIG. 12 to have a higher threshold voltage than if the P-WELLs 26a and 26b were not formed. Accordingly, dark current from interface traps between the isolation structures 31 and 32 and the channel region does not flow because of the P-WELLs 26a and 26b surrounding the isolation structures 31 and 32.

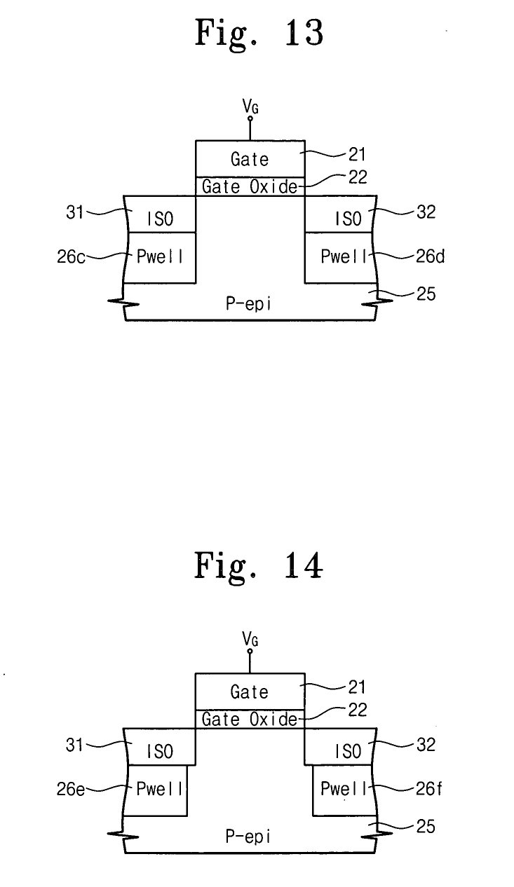

The epitaxial type NMOSFET of FIG. 13 is similar to the epitaxial type NMOSFET of FIG. 12 except that the epitaxial type NMOSFET of FIG. 13 includes P-WELLs 26c and 26d formed under the isolation structures 31 and 32, respectively. In FIG. 13, the P-WELLs 26c and 26d are formed under the isolation structures 31 and 32, respectively, without extending into the channel region under the gate 21. In addition, the P-WELLs. 26c and 26d in FIG. 13 are formed with full alignment under the isolation structures 31 and 32, respectively. Thus, the sidewalls of the P-WELLs 26c and 26d in FIG. 13 are aligned to the sidewalls of the isolation structures 31 and 32, respectively.

The epitaxial type NMOSFET of FIG. 14 is similar to the epitaxial type NMOSFET of FIG. 13 except that the epitaxial type NMOSFET of FIG. 14 includes P-WELLs 26e and 26f formed with partial alignment under the isolation structures 31 and 32, respectively. Another words, the sidewalls of the P-WELLs 26e and 26f are not aligned to the sidewalls of the isolation structures 31 and 32, respectively.

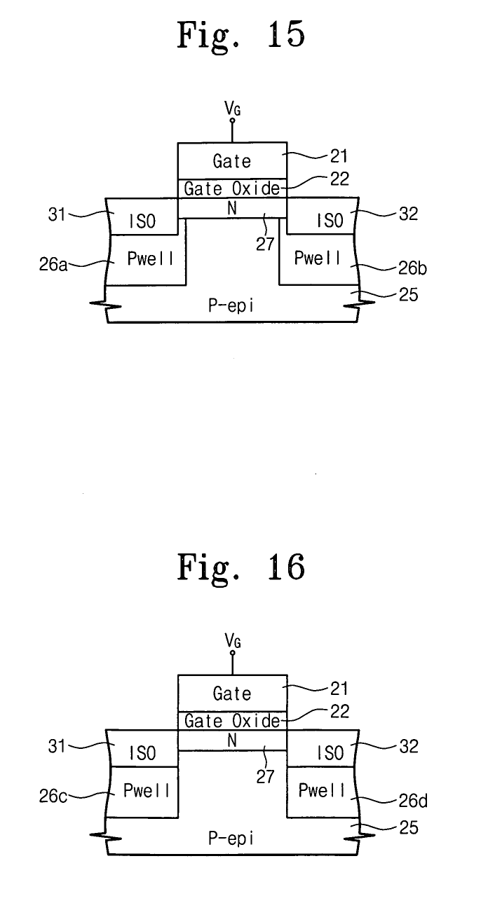

FIGS. 15, 16, 17, 18, 19, and 20 are cross-sectional views of the depletion type NMOSFET of FIG. 9 along the line B of FIG. 6.

Referring to FIG. 15, the N-type doped channel region 27 is formed in the P-type epitaxial layer 25 such that the NMOSFET of FIG. 15 has the negative threshold voltage. Referring to FIGS. 6, 9, and 15, the source and drain regions 31 and 32 are formed to abut the channel region 27 along the first direction A in FIG. 6, and the isolation structures 31 and 32 are formed to abut the channel region 27 disposed under the gate 21 along the second direction B in FIG. 6.

In addition in FIG. 15, P-WELLs 26a and 26b are formed to partially surround the isolation structures 31 and 32 and extend into the channel region under the N-type doped channel region 27. Such P-WELLs 26a and 26b increase the threshold voltage of the NMOSFET of FIG. 15 and decrease the dark current without an interface between the isolation structures 31 and 32 and the P-type epitaxial layer 25.

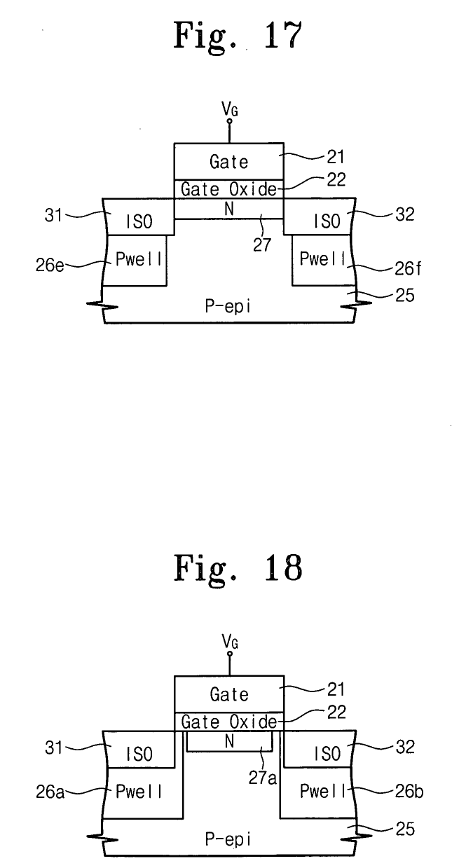

The depletion type NMOSFET of FIG. 16 is similar to the depletion type NMOSFET of FIG. 15 except that P-WELLs 26c and 26d are formed with full alignment under the isolation structures 31 and 32, respectively, similar to FIG. 13. The depletion type NMOSFET of FIG. 17 is similar to the depletion type NMOSFET of FIG. 16 except that P-WELLs 26e and 26f are formed with partial alignment under the isolation structures 31 and 32, respectively, similar to FIG. 14.

The depletion type NMOSFETs of FIGS. 15, 16, and 17 have the N-type doped channel region 27 abutting the isolation structures 31 and 32. The depletion type NMOSFETs of FIGS. 18, 19, and 20 are similar to the depletion type NMOSFETs of FIGS. 15, 16, and 17, respectively, except that the N-type doped channel region 27 in FIGS. 18, 19, and 20 does not abut the isolation structures 31 and 32. Thus, portions of the P-type epitaxial layer 25 are disposed between the N-type doped channel region 27 and the isolation structures 31 and 32 in FIGS. 18, 19, and 20.

The present invention may also be practiced with other types of transistors aside from the examples illustrated in FIGS. 7, 8, 9, 10, 11, 12, 13, 14, 15, 16, 17, 18, 19, and 20. In addition, the present invention may also be practiced with P-channel field effect transistors rather than the N-channel field effect transistors of FIGS. 7, 8, 9, 10, 11, 12, 13, 14, 15, 16, 17, 18, 19, and 20.

In this manner, the leakage current breaker voltage is applied at the bit lines of the APS array 110 for preventing the leakage current through the select transistors of the unselected pixels. With minimized leakage current, the select transistors of the selected row may output signals with high integrity.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

The present invention is limited only as defined in the following claims and equivalents thereof.

What is claimed is:

1. An image pickup device comprising:
an active pixel sensor having a plurality of pixels;
a row driver that selects at least one pixel to be activated to output signals;
and
a leakage current breaker that prevents a respective leakage current through each of at least one unselected pixel.

2. The image pickup device of claim 1, wherein the leakage current breaker includes:
a respective leakage current breaker circuit coupled to each bit line for a respective column of pixels of the active pixel sensor.

3. The image pickup device of claim 2, wherein the respective leakage current breaker circuit applies a respective leakage current breaker voltage at each bit line when a select control signal for a selected row is activated, wherein a level of the activated leakage current breaker voltage is greater than a level of a deactivated select control signal applied to the unselected pixel.

4. The image pickup device of claim 3, further comprising:
a plurality of select transistors for the pixels coupled to a bit line, with a respective select transistor for the selected row being turned on and remaining select transistors for the unselected rows being turned off from application of the respective leakage current breaker voltage at the bit line.

5. The image pickup device of claim 4, wherein all respective select transistors for a selected row of the active pixel sensor are turned on and wherein all respective select transistors for unselected rows of the active pixel sensor are turned off from application of the respective leakage current breaker voltage at all the bit lines of the active pixel sensor.

6. The image pickup device of claim 4, wherein the select transistors are depletion or epitaxial type MOSFETs (metal oxide semiconductor field effect transistors).

7. The image pickup device of claim 6, wherein each epitaxial type MOSFET includes:
a source;
a drain;
an epitaxial-region disposed between the source and the drain, with a channel being disposed in the epitaxial-region between the source and the drain;
a gate oxide disposed on the epitaxial-region; and
a gate electrode disposed over the gate oxide.

8. The image pickup device of claim 6, wherein each epitaxial type MOSFET further includes:
a doped channel region formed by doping, with a first dopant of a first conductivity type, the epitaxial-region that is of a second conductivity type opposite to the first conductivity type.

9. The image pickup device of claim 6, wherein each depletion or epitaxial type MOSFET includes:
a source and a drain formed along a first direction;
a channel region between the source and the drain;
isolation structures formed to abut the channel region along a second direction;
a gate oxide disposed on the channel region; and
a gate electrode disposed over the gate oxide.

10. The image pickup device of claim 9, wherein each depletion or epitaxial type MOSFET further includes:
a respective well that is formed to surround each isolation structure including into the channel region under the gate oxide.

11. The pickup device of claim 9, wherein each depletion or epitaxial type MOSFET further includes:
a respective well that is formed to be under each isolation structure with full alignment.

12. The pickup device of claim 9, wherein each depletion or epitaxial type MOSFET further includes:
a respective well that is formed to be under each isolation structure with partial alignment.

13. The pickup device of claim 9, wherein the gate oxide is disposed on the channel region formed by an epitaxial region.

14. The pickup device of claim 9, wherein the gate oxide is disposed on the channel region formed by a well.

15. The pickup device of claim 9, wherein each depletion or epitaxial type MOSFET further includes:
a doped channel region formed by doping, with a first dopant of a first conductivity type, the channel region that is of a second conductivity type opposite to the first conductivity type.

16. The pickup device of claim 15, wherein the doped channel region does not abut the isolation structures.

17. The pickup device of claim 15, wherein the doped channel region abuts the isolation structures.

18. An image pickup device comprising:
an active pixel sensor having a plurality of pixels with each pixel including:
a respective photo-diode for generating charge signals from received light; and
a respective pixel circuit comprised of at least one epitaxial type transistor for generating electrical signals from the charge signals of the respective photo-diode, wherein the epitaxial transistor includes:
a source;
a drain;
an epitaxial-region disposed between the source and the drain, with a channel region being formed in the epitaxial-region between the source and the drain;
a gate oxide disposed on the epitaxial-region; and
a gate electrode disposed over the gate oxide.

19. The image pickup device of claim 18, wherein the epitaxial transistor further includes:
a doped channel region formed by doping, with a first dopant of a first conductivity type, the channel region that is of a second conductivity type opposite to the first conductivity type.

20. The image pickup device of claim 18, wherein the drain and the source are formed along a first direction, and wherein the epitaxial transistor further includes:
isolation structures formed to abut the channel region along a second direction; and
a respective well that is formed to surround each isolation structure including into the channel region under the gate oxide.
